(19) United States
(12) Patent Application Publication
(10) Pub. No.: US 2018/0073764 A1
(43) Pub. Date: Mar. 15, 2018

(54) PHASE-CHANGE COOLING APPARATUS AND METHOD OF CONTROLLING THE SAME

(71) Applicants: NEC Corporation, Minato-ku, Tokyo (JP); NEC Facilities, Ltd., Minato-ku, Tokyo (JP)

(72) Inventors: Minoru YOSHIKAWA, Tokyo (JP); Kazuo WATANABE, Tokyo (JP); Masanori SATO, Tokyo (JP); Arihiro MATSUNAGA, Tokyo (JP)

(73) Assignees: NEC Corporation, Minato-ku, Tokyo (JP); NEC Facilities, Ltd., Minato-ku, Tokyo (JP)

(21) Appl. No.: 15/561,633

(22) PCT Filed: Mar. 30, 2016
(86) PCT No.: PCT/JP2016/001826

§ 371 Date: Sep. 26, 2017

(30) Foreign Application Priority Data
Apr. 1, 2015 (JP) 2015-074820

(51) Int. Cl. F24F 11/053; F28D 15/06; F24F 3/044; G06F 1/20; H05K 7/20

(52) U.S. Cl. CPC F24F 11/053; F28D 15/06; H05K 7/20145; G06F 1/20; F24F 3/044

(57) ABSTRACT

A cooling system employing a phase-change cooling apparatus together with an air conditioner becomes complex and increases in cost if it is configured to maximize the efficiency of the entire cooling system; therefore, a phase-change cooling apparatus according to an exemplary aspect of the present invention includes a heat receiving means for vaporizing refrigerant liquid stored and producing refrigerant vapor by receiving heat exhausted from a heating section having breathed in cold air; a heat radiation means for liquefying the refrigerant vapor and producing refrigerant liquid by radiating heat of the refrigerant vapor to cooling air by a fan; a vapor tube connecting the heat receiving means to the heat radiation means, the refrigerant vapor mainly flowing through the vapor tube; a liquid tube connecting the heat receiving means to the heat radiation means, the refrigerant liquid mainly flowing through the liquid tube; and a control means for controlling a rotation rate of the fan, wherein the control means controls the rotation rate of the fan so that a vapor temperature that is a temperature of the refrigerant vapor may approach an intake-air temperature that is a temperature of the cold air.

### TECHNICAL FIELD

The present invention relates to phase-change cooling apparatuses and methods of controlling the phase-change cooling apparatuses and, in particular, to a phase-change cooling apparatus to be used with an air conditioner and a method of controlling the phase-change cooling apparatus.

### BACKGROUND ART

In recent years, with the Internet and the like expanding, a data center has an increasing role where servers and network apparatuses for information processing are brought together in one place. The electricity consumption by the data center also increases with the throughput to be processed increasing. Particularly, the data center requires a large amount of electric power consumed by air conditioners used for cooling electronic devices, which accounts for almost half of the total power consumption of the data center. Consequently, it is required to reduce the electric power consumed by air conditioners in the data center.

Patent Literature 1 discloses an example of an air-conditioning system to be installed in such a data center. The related air-conditioning system using outside air described in Patent Literature 1 further includes an outside air heat exchange system in addition to a common air-conditioning system. The outside air heat exchange system includes a related air-cooled heat exchanger, a heat exchanger, a pump, a pipe, and a control device.

The related air-cooled heat exchanger includes a heat exchanger body, a fan, and the like. The air-cooled heat exchanger is provided with a thermometer to measure the temperature of cold air, a thermometer to measure exhaust temperature, a power meter to measure the power consumption by the pump, a power meter to measure the power consumption by the fan, and a rotation rate control device to control the rotation of the fan.

The control device calculates the amount of heat exchange using an air temperature difference that is a difference between the exhaust air temperature and the cold air temperature, and an air volume of the fan that is calculated from the rotation rate of the fan. A coefficient of performance (COP) is calculated from the amount of heat exchange, the power consumption by the pump, and the power consumption by the fan. The control device is configured to control the rotation rate of the fan so as to improve the coefficient of performance.

It is said that the related air-conditioning system using outside air with the configuration makes it possible to operate at peak efficiency in any outside air condition and achieve a saving of energy.

### CITATION LIST

### Patent Literature

[PTL 1] Japanese Unexamined Patent Application Publication No. 2012-193903

### SUMMARY OF INVENTION

### Technical Problem

As mentioned above, the related outside-air heat exchange system described in Patent Literature 1 includes power meters to measure the power consumption of the pump and the fan. However, if a cooling system is configured to measure the total power consumption of a substantial number of cooling devices installed in a large building as is the case with a data center and calculate the coefficient of performance (COP) from the measurement results and perform a control, such a cooling system has the following disadvantages. That is to say, the cooling system has the problem that it is made complicated by the need to install power feeding systems together in respective cooling devices and the need to separate a power system for a refrigerator included in the air conditioner from a power system for a blower into another system, which results in a cost increase.

In particular, the amount of heat generation of a server and the like installed in the data center fluctuates a lot depending on their operational conditions. This causes the coefficient of performance (COP) to deteriorate, in the above-mentioned complicated system configuration in which the power consumption of the cooling system is measured, and a rotation control of the fan in an outdoor unit is performed after performing arithmetic processing on the measurement results, during the time required to measure it and perform the arithmetic processing.

As mentioned above, there has been the problem that a cooling system employing a phase-change cooling apparatus together with an air conditioner becomes complex and increases in cost if it is configured to maximize the efficiency of the entire cooling system.

The object of the present invention is to provide a phase-change cooling apparatus and a method of controlling the phase-change cooling apparatus that solve the above-mentioned problem that a cooling system employing a phase-change cooling apparatus together with an air conditioner becomes complex and increases in cost if it is configured to maximize the efficiency of the entire cooling system.

### Solution to Problem

A phase-change cooling apparatus according to an exemplary aspect of the present invention includes a heat receiving means for vaporizing refrigerant liquid stored and producing refrigerant vapor by receiving heat exhausted from a heating section having breathed in cold air; a heat radiation means for liquefying the refrigerant vapor and producing refrigerant liquid by radiating heat of the refrigerant vapor to cooling air by a fan; a vapor tube connecting the heat receiving means to the heat radiation means, the refrigerant vapor mainly flowing through the vapor tube; a liquid tube connecting the heat receiving means to the heat radiation means, the refrigerant liquid mainly flowing through the liquid tube; and a control means for controlling a rotation rate of the fan, wherein the control means controls the rotation rate of the fan so that a vapor temperature that is a temperature of the refrigerant vapor may approach an intake-air temperature that is a temperature of the cold air.

A method of controlling a phase-change cooling apparatus according to an exemplary aspect of the present invention, on a phase-change cooling apparatus including a heat receiving means for vaporizing refrigerant liquid stored and producing refrigerant vapor by receiving heat exhausted from a heating section having breathed in cold air; a heat radiation means for liquefying the refrigerant vapor and producing refrigerant liquid by radiating heat of the refrigerant vapor to cooling air by a fan; a vapor tube connecting the heat receiving means to the heat radiation means, the refrigerant vapor mainly flowing through the vapor tube; a liquid tube connecting the heat receiving means to the heat radiation means, the refrigerant liquid mainly flowing through the liquid tube, the method includes controlling a rotation rate of the fan so that a vapor temperature that is a temperature of the refrigerant vapor may approach an intake-air temperature that is a temperature of the cold air.

### Advantageous Effects of Invention

According to the phase-change cooling apparatus and the method of controlling the phase-change cooling apparatus of the present invention, it is possible in a cooling system employing a phase-change cooling apparatus together with an air conditioner to maximize the efficiency of the entire cooling system with a simple configuration and at low cost.

### BRIEF DESCRIPTION OF THE DRAWINGS

FIG. 1 is a block diagram illustrating a configuration of a phase-change cooling apparatus according to a first example embodiment of the present invention.

FIG. 2 is a block diagram illustrating a configuration of a phase-change cooling system according to the first example embodiment of the present invention.

FIG. 3 is diagram to illustrate the heat exchanging performance of the phase-change cooling system according to the first example embodiment of the present invention.

FIG. 4 is a flowchart to explain an operation of a controller included in the phase-change cooling apparatus according to the first example embodiment of the present invention.

FIG. 5 is a diagram to illustrate conditions of heat exchange in the phase-change cooling apparatus according to the first example embodiment of the present invention with the outside air temperature decreasing.

FIG. 6 is a diagram to illustrate conditions of heat exchange in the phase-change cooling apparatus according to the first example embodiment of the present invention with the outside air temperature increasing.

FIG. 7 is a diagram illustrating a relationship between the radiation performance of a heat radiator and a temperature difference in the heat radiator included in the phase-change cooling apparatus according to the first example embodiment of the present invention.

FIG. 8 is a diagram to illustrate conditions of heat exchange in the phase-change cooling apparatus according to the first example embodiment of the present invention in controlling it so that the temperature difference in the heat radiator may become equal to a threshold temperature difference.

FIG. 9 is a diagram to explain an operation of a controller included in a phase-change cooling apparatus according to a second example embodiment of the present invention and illustrating a relationship between a temperature difference in a heat radiator and the outside air temperature.

FIG. 10 is a block diagram illustrating another configuration of the phase-change cooling system according to example embodiments of the present invention.

FIG. 11 is a block diagram illustrating yet another configuration of the phase-change cooling system according to example embodiments of the present invention.

### [Example Embodiment]

Example embodiments of the present invention will be described with reference to drawings below.

### (First Example Embodiment)

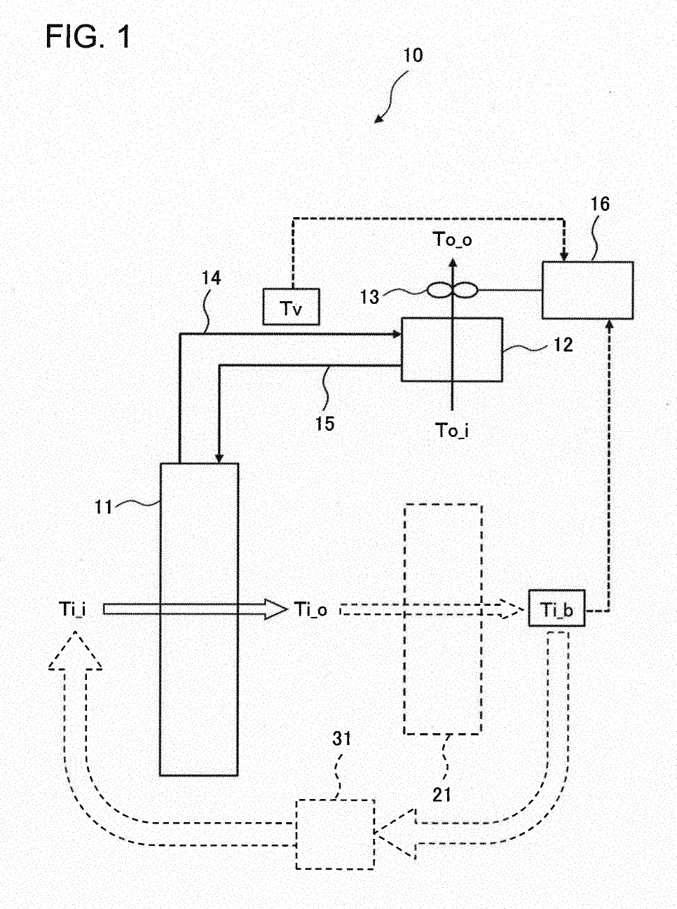

FIG. 1 is a block diagram illustrating a configuration of a phase-change cooling apparatus 10 according to a first example embodiment of the present invention. The phase-change cooling apparatus 10 according to the present example embodiment includes a heat receiving section 11, a heat radiator 12, a fan 13, a vapor tube 14, a liquid tube 15, and a controller 16.

The heat receiving section 11 produces refrigerant vapor using, as the evaporation heat of the refrigerant, the exhaust heat included in the warm air exhausted from a heating section 31 having breathed in cold air. The heat radiator 12 radiates heat of the refrigerant vapor through the cooling air by the fan 13, liquefies the refrigerant vapor, and produces refrigerant liquid. The vapor tube 14, through which the refrigerant vapor mainly flows, connects the heat receiving section 11 to the heat radiator 12. The liquid tube 15, through which the refrigerant liquid mainly flows, connects the heat receiving section 11 to the heat radiator 12.

The controller 16 controls the rotation rate of the fan 13. The controller 16 controls the rotation rate of the fan 13 so that a vapor temperature Tv that is a temperature of the refrigerant vapor may approach an intake-air temperature Ti_b that is a temperature of the cold air at a range not in excess of the intake-air temperature Ti_b.

A cooling system employing the phase-change cooling apparatus 10 according to the present example embodiment further includes an air conditioner 21. The heat receiving section 11 takes in the warm air, cools it, and exhausts an air blast reaching an outlet temperature Ti_o. The air conditioner 21 takes in the air blast, produces cold air at the intake-air temperature Ti_b, and sends it to the heating section 31.

Next, the phase-change cooling apparatus and the cooling system employing the phase-change cooling apparatus according to the present example embodiment will be described in further detail using as an example a case in which they are installed in a data center or the like. A cooling system employing a phase-change cooling apparatus will be referred to simply as a phase-change cooling system below.

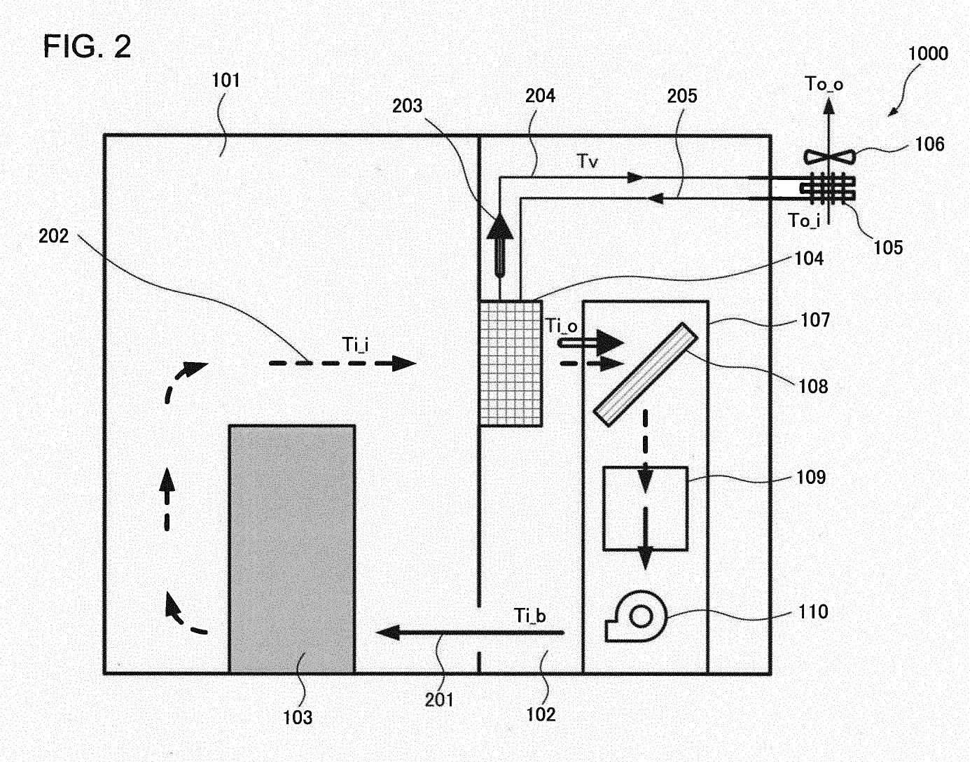

FIG. 2 is a block diagram illustrating the configuration of a phase-change cooling system 1000 according to the first example embodiment of the present invention. As illustrated in FIG. 2, the phase-change cooling system 1000 according to the present example embodiment includes a heat receiving section 104 that is placed on the windward side of a heat exchanger 108 included in an air conditioner 107. The alphabetical coded characters in the figure represent temperatures: an inlet temperature Ti_i and an outlet temperature Ti_o of the air flowing through the heat receiving section 104, an inlet temperature To_i and an outlet temperature To_o of the air flowing through a heat radiator 105, a vapor temperature Tv, and an intake-air temperature Ti_b of a cold aisle or a rack. The phase-change cooling system 1000 is configured to monitor these temperatures and control a fan 106 of an outdoor unit based on the monitored temperatures.

In the present example embodiment, the heat receiving section 104 constituting the phase-change cooling system 1000 is placed on the wall that separates a server room 101 in which a server rack 103 serving as a heating section is placed from a machine room 102 in which the air conditioner 107 is placed. The heat receiving section 104 may be placed on the side of the server room 101 or on the side of the machine room 102. In other words, it is only necessary to place the heat receiving section 104 so that a current of air flowing into the machine room 102 may become a current of air having passed through the heat receiving section 104. A vapor tube 204 and a liquid tube 205 are connected to the heat receiving section 104, the vapor tube 204 is configured through which the refrigerant having phase-changed from liquid to vapor transports heat 203, and the liquid tube 205 is configured through which the refrigerant liquid circulates that has phase-changed to liquid after being cooled by the fan 106 in the heat radiator 105 placed in an outdoor location.

As mentioned above, the heat receiving section 104 is disposed on the windward side of the heat exchanger 108 that performs an exchange of heat with the cold water produced by a refrigerator 109 constituting the air conditioner 107. This causes warm air 202 having cooled the server rack 103 to be heat-exchanged in the air conditioner 107 after the heat receiving section 104 draws the heat 203 from the warm air 202; consequently, it is possible to reduce the power consumption of the refrigerator 109 that produces the cold water. A blower 110 included in the air conditioner 107 supplies cold air 201 to the server rack 103.

The power consumed by the refrigerator 109 is an order of or more magnitude greater than the power consumed by the fan 106 of the outdoor unit constituting the phase-change cooling apparatus. The phase-change cooling system 1000 according to the present example embodiment, therefore, is configured to control only the fan 106 of the outdoor unit constituting the phase-change cooling apparatus. This makes it possible to minimize additional electric power required to cool the data center. That is to say, according to the phase-change cooling apparatus and the phase-change cooling system of the present example embodiment, it is possible in a cooling system employing a phase-change cooling apparatus together with an air conditioner to maximize the efficiency of the entire cooling system with a simple configuration and at low cost.

Next, the operation of the phase-change cooling apparatus 10 and the phase-change cooling system 1000 according to the present example embodiment will be described.

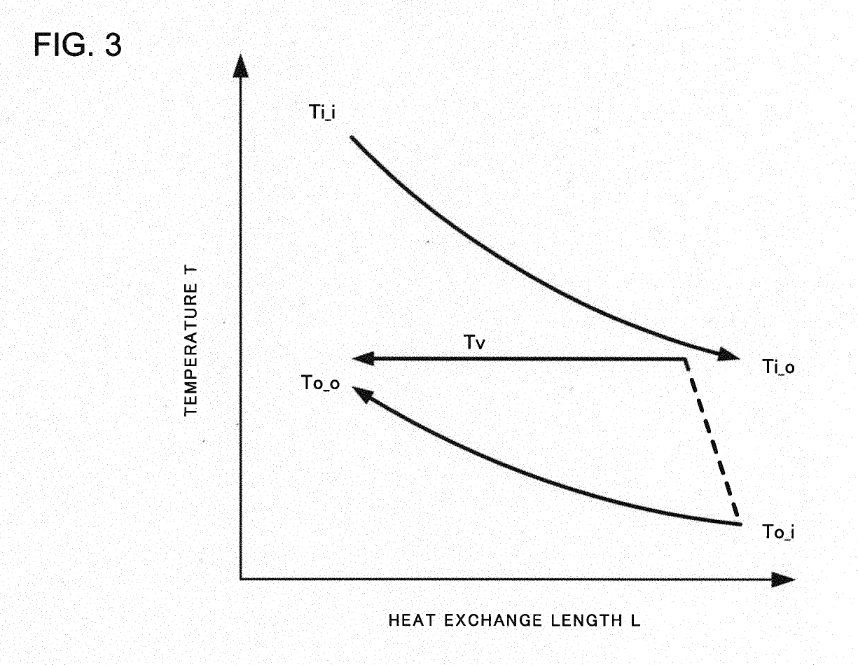

The FIG. 3 illustrates the heat exchanging performance of the phase-change cooling system 1000. The horizontal axis represents heat exchange length L, and the vertical axis represents temperature T. The warm air 202 at an inlet temperature Ti_i at an inlet port of the heat receiving section 104 is cooled by the heat exchange with outside air at an inlet temperature To_i in the heat radiator 105, and exhausted from the heat receiving section 104 reaching an outlet temperature Ti_o. In reverse, the temperature of the outside air in the heat radiator 105 increases by the amount of heat exchange, and the air is exhausted reaching an outlet temperature To_o. Because the phase-change cooling system 1000 according to the present example embodiment performs a phase-change cooling using latent heat of the refrigerant, the heat exchange in each of the heat receiving section 104 and the heat radiator 105 is performed based on a difference from the vapor temperature Tv. The vapor temperature Tv is constant because the heat is transferred due to latent heat.

When all of the heat generated in the server rack 103, that is, one-hundred percent of the heat, is drawn by phase-change cooling, the outlet temperature Ti_o of the air exhausted from the heat receiving section decreases to the intake-air temperature Ti_b at the cold aisle or the rack. In this a case, it is unnecessary for the air conditioner 107 to produce cold water in the refrigerator 109 and perform the heat exchange in the heat exchanger 108. This makes it possible to cause the air conditioner 107 to stop operation; therefore, it is possible to reduce drastically the power consumption of the entire phase-change cooling system 1000.

The heat exchange is not performed unless the vapor temperature Tv is equal to or lower than the intake-air temperature Ti_b at the rack. Therefore, it is necessary for the vapor temperature Tv to be equal to or lower than the intake-air temperature Ti_b at the rack in order to draw one-hundred percent of the heat generated in the server rack 103 by phase-change cooling and equalize the outlet temperature Ti_o of the air exhausted from the heat receiving section to the intake-air temperature Ti_b at the rack. This makes it possible to judge whether or not one-hundred percent of the heat generated in the server rack 103 is drawn by phase-change cooling from a magnitude relationship between the vapor temperature Tv and the intake-air temperature Ti_b at the rack.

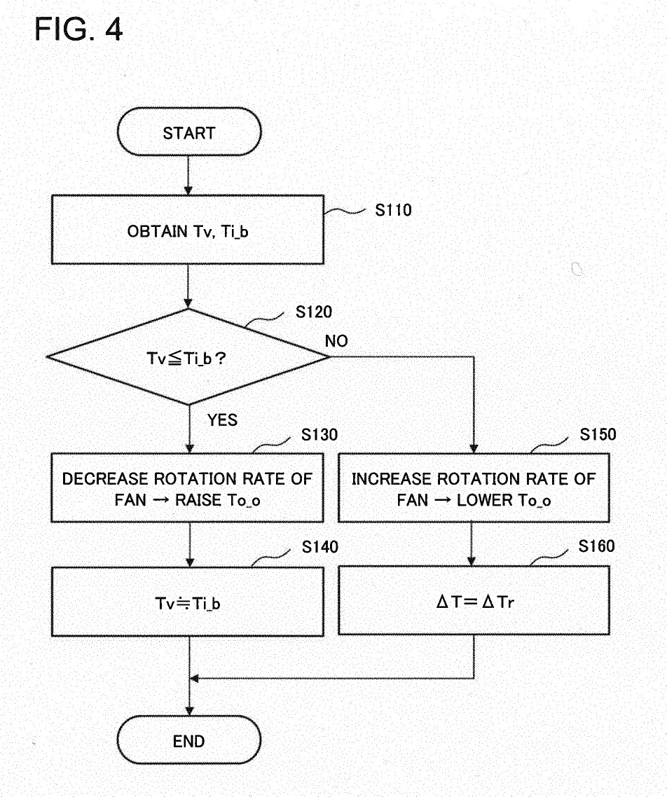

Next, the operation of the controller 16 included in the phase-change cooling apparatus 10 according to the present example embodiment will be described. FIG. 4 is a flowchart to explain the operation of the controller 16 included in the phase-change cooling apparatus 10 according to the present example embodiment.

First, the controller 16 included in the phase-change cooling apparatus 10 obtains the vapor temperature Tv and the intake-air temperature Ti_b at the server rack 103 serving as the heating section 21 (step S110). The intake-air temperature Ti_b is a temperature of the cooling air (cold air) to ensure the operation of the server rack 103 and a setting value predetermined in accordance with the specifications and the like of the server rack 103. The vapor temperature Tv can be a value obtained by measuring the surface temperature of the vapor tube 14. The controller 16 compares the magnitude of the vapor temperature Tv and the intake-air temperature Ti_b (step S120).

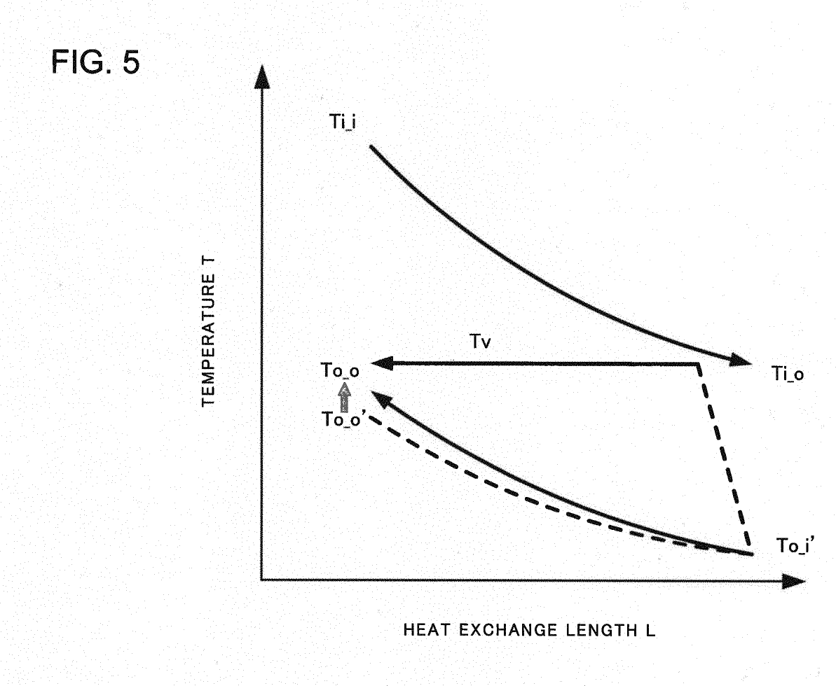

If the outside air temperature decreases from To_i to To_i′, or the amount of heat generation of the server rack 103 becomes smaller, the vapor pressure of the refrigerant reduces; consequently, the boiling point of the refrigerant, that is, the vapor temperature Tv also decreases. As a result, the vapor temperature Tv becomes smaller than the intake-air temperature Ti_b (step S120/YES), and a capacity for drawing heat of phase-change cooling improves. In this case, the controller 16 instructs the fan 13 in the heat radiator 12 to decrease the rotation rate, and raises the outlet temperature To_o′ of the heat radiator 12 to To_o (step S130). This enables the power consumption of the fan 13 to reduce. FIG. 5 illustrates the conditions of heat exchange in the phase-change cooling apparatus 10.

A this time, the controller 16 controls the rotation rate of the fan so that the vapor temperature Tv may approach the intake-air temperature Ti_b until the vapor temperature Tv becomes approximately equal to the intake-air temperature Ti_b of the rack, that is, at a range where the vapor temperature Tv is not in excess of the intake-air temperature Ti_b (step S140). The reason why “a range not in excess” is defined is that a vapor temperature Tv exceeding the intake-air temperature Ti_b makes it impossible to perform the heat exchange; specifically, for example, the control can be performed so that the vapor temperature Tv may become lower than the intake-air temperature Ti_b by approximately one degree Celsius.

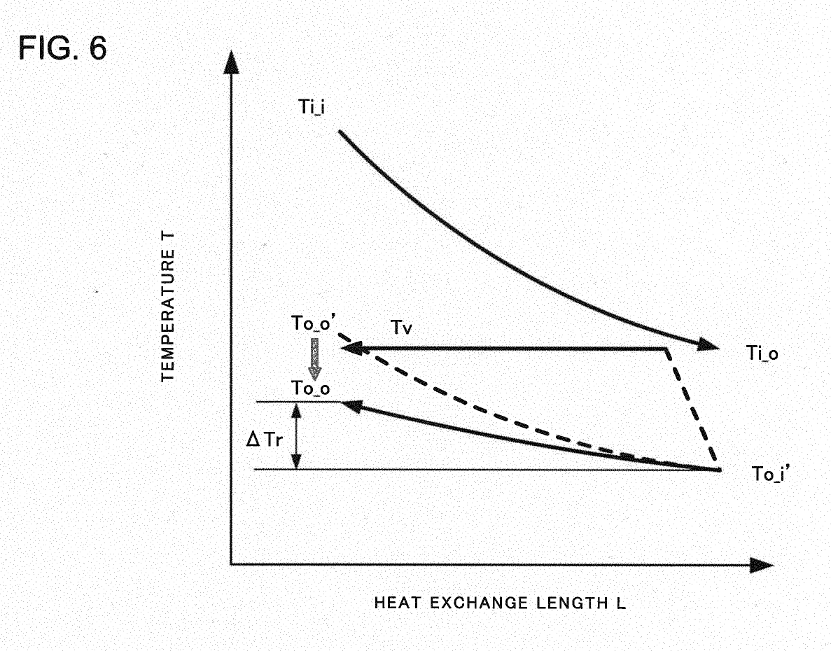

In reverse, if the outside air temperature increases from To_i to To_i′, or the amount of heat generation of the server rack 103 increases, the vapor temperature Tv increases; consequently, the vapor temperature Tv becomes larger than the intake-air temperature Ti_b (step S120/No). Then the controller 16 improves the capacity for drawing heat of phase-change cooling by increasing the rotation rate of the fan 13 in the heat radiator 12, and lowers the outlet temperature To_o′ of the heat radiator 12 to To_o (step S150). FIG. 6 illustrates the conditions of heat exchange at this time in the phase-change cooling apparatus 10.

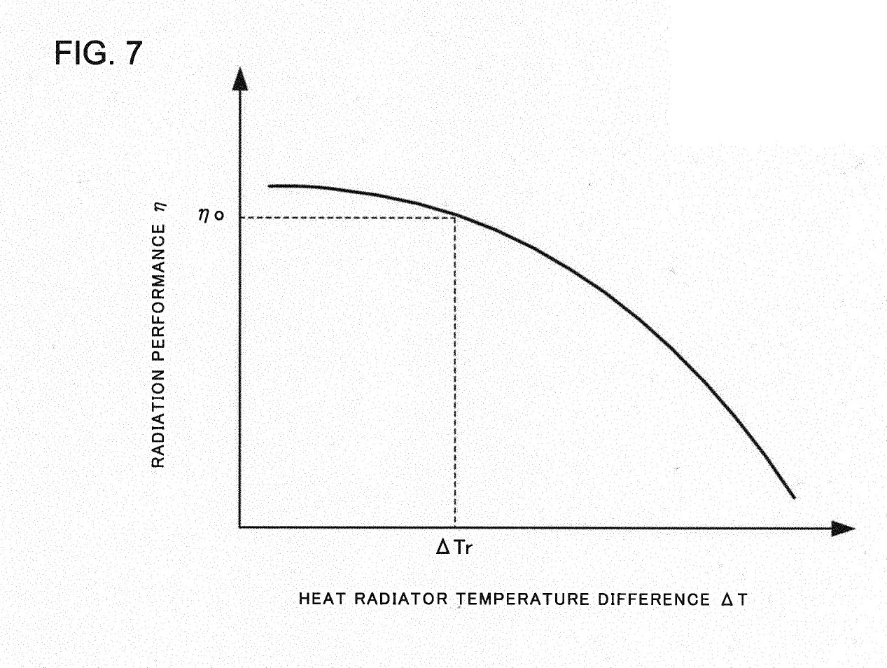

As illustrated in FIG. 7, the radiation performance η of the heat radiator 12 depends on a heat radiator temperature difference ΔT between the inlet temperature To_i of the cooling air flowing into the heat radiator 12 and the outlet temperature To_o of the cooling air flowing away from the heat radiator 12, and becomes approximately constant when the temperature difference drops to below a certain value. The controller 16 can be configured to set in advance a threshold temperature difference ΔTr below which the radiation performance η becomes approximately constant (η₀) and control the rotation rate of the fan 13 so that the difference between the inlet temperature To_i and the outlet temperature To_o of the heat radiator 12 may become equal to ΔTr (step S160). This enables the power consumption of the fan to be minimized.

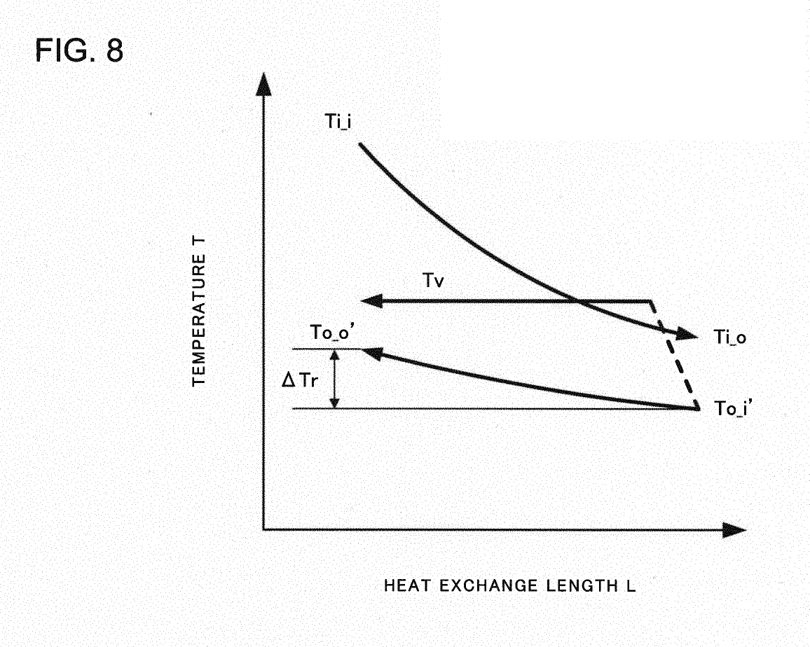

As mentioned above, if the rotation rate of the fan 13 is controlled so that the heat radiator temperature difference ΔT may become equal to the threshold temperature difference ΔTr, the vapor temperature Tv can exceed or even equal the intake-air temperature Ti_b at the rack as illustrated in FIG. 8. In this case, the phase-change cooling apparatus 10 can be configured to heat-exchange only the amount of heat that cannot be drawn by phase-change cooling, by using the heat exchanger 108 included in the air conditioner 21 (107). If the outside air temperature To_i′ or the amount of heat generation of the server rack 103 decreases while the rotation rate of the fan 13 is being controlled so as to equalize the heat radiator temperature difference ΔT to the threshold temperature difference ΔTr, the heat radiator temperature difference ΔT becomes smaller than the threshold temperature difference ΔTr. In this case, the controller 16 can perform a control so as to decrease the rotation rate of the fan 13.

In the above descriptions, the controller 16 compares the magnitude of the vapor temperature Tv and the intake-air temperature Ti_b, and controls the rotation rate of the fan 13 in the heat radiator 12 based on the comparison results. However, the present example embodiment is not limited to this. A value obtained by measuring a heat receiving section outlet temperature Ti_o that represents a temperature of exhaust air from the heat receiving section 11 may be used as the vapor temperature Tv. The controller 16 can be configured to compare the magnitude of the heat receiving section outlet temperature Ti_o and the intake-air temperature Ti_b at the rack, and controls the rotation rate of the fan 13 in the heat radiator 12 based on the comparison results. In this case, because the monitor control system can be simplified, it is possible to reduce cost and improve reliability of the phase-change cooling apparatus 10.

Next, a method of controlling a phase-change cooling apparatus according to the present example embodiment will be described.

The controlled object of the method of controlling a phase-change cooling apparatus according to the present example embodiment is a phase-change cooling apparatus including a heat receiving section, a heat radiator, a fan, a vapor tube, and a liquid tube.

The heat receiving section produces refrigerant vapor using, as the evaporation heat of the refrigerant, the exhaust heat included in the warm air exhausted from a heating section having breathed in cold air. The heat radiator radiates heat of the refrigerant vapor through the cooling air by the fan, liquefies the refrigerant vapor, and produces refrigerant liquid. The vapor tube, through which the refrigerant vapor mainly flows, connects the heat receiving section to the heat radiator. The liquid tube, through which the refrigerant liquid mainly flows, connects the heat receiving section to the heat radiator.

With respect to the phase-change cooling apparatus having the above-described configuration, the method of controlling a phase-change cooling apparatus according to the present example embodiment includes controlling the rotation rate of the fan so that a vapor temperature of a temperature of the refrigerant vapor may approach an intake-air temperature of a temperature of the cold air at a range not in excess of the intake-air temperature.

The controlling the rotation rate of the fan can include comparing the magnitude of the vapor temperature and the intake-air temperature, and decreasing the rotation rate of the fan if it is determined that the vapor temperature is not larger than the intake-air temperature.

The controlling the rotation rate of the fan can include comparing the magnitude of the vapor temperature and the intake-air temperature, and increasing the rotation rate of the fan if it is determined that the vapor temperature is larger than the intake-air temperature. In this case, the method may include controlling the rotation rate of the fan so that a heat radiator temperature difference may become approximately equal to a threshold temperature difference, where the heat radiator temperature difference is a difference between the inlet temperature that is a temperature of the cooling air flowing into the heat radiator and an outlet temperature that is a temperature of the cooling air flowing away from the heat radiator, and the threshold temperature difference is a temperature difference below which the radiation performance of the heat radiator becomes approximately constant.

As mentioned above, according to the phase-change cooling apparatus and the method of controlling the phase-change cooling apparatus of the present invention, it is possible in a cooling system employing a phase-change cooling apparatus together with an air conditioner to maximize the efficiency of the entire cooling system with a simple configuration and at low cost.

### (Second Example Embodiment)

Next, a second example embodiment of the present invention will be described.

In the phase-change cooling apparatus 10 according to the first example embodiment, the vapor temperature Tv, the inlet temperature To_i of the heat radiator 12, the intake-air temperature Ti_b, and the inlet temperature Ti_i of the air in the heat receiving section 11, which have been described above, can set in advance depending on design conditions and installation environment. In the present example embodiment, the operation of the controller 16 in this case will be described.

The amount of heat generation from each server rack serving as a heating section 31 varies significantly due to load variation; however, the amount of heat generation can hover at approximately constant amount for the whole of the server room. In this case, the capacity for drawing heat of the phase-change cooling apparatus 10 is affected only by the inlet temperature To_i at the heat radiator 12, that is, the outside air temperature Ta.

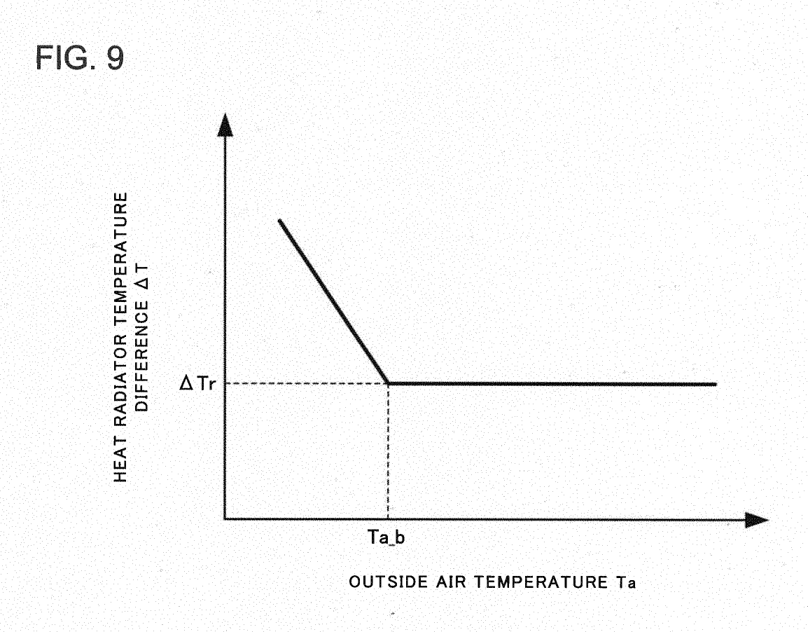

The controller included in the phase-change cooling apparatus according to the present example embodiment controls the rotation rate of the fan based on the outside air temperature Ta that is a temperature of the outside air flowing into the heat radiator. FIG. 9 illustrates the relationship between the heat radiator temperature difference ΔT and the outside air temperature Ta in this case. The heat radiator temperature difference ΔT, as mentioned above, is a difference between the inlet temperature To_i of the cooling air flowing into the heat radiator 12 and the outlet temperature To_o of the cooling air flowing away from the heat radiator 12.

If the outside air temperature Ta is not larger than a threshold outside air temperature Ta_b that is predetermined, the controller controls the rotation rate of the fan so that an outlet temperature To_o that is a temperature of the cooling air flowing away from the heat radiator may become constant. That is to say, the rotation rate of the fan is decreased as the outside air temperature Ta decreases.

In contrast, if the outside air temperature Ta is larger than the predetermined threshold outside air temperature, the controller controls the rotation rate of the fan so that a threshold temperature difference ΔTr may become constant, where the threshold temperature difference is a heat radiator temperature difference below which the radiation performance of the heat radiator becomes approximately constant.

As describe above, according to the phase-change cooling apparatus of the present example embodiment, it is possible to reduce cost and improve reliability of the phase-change cooling apparatus because the monitor control system can be simplified further.

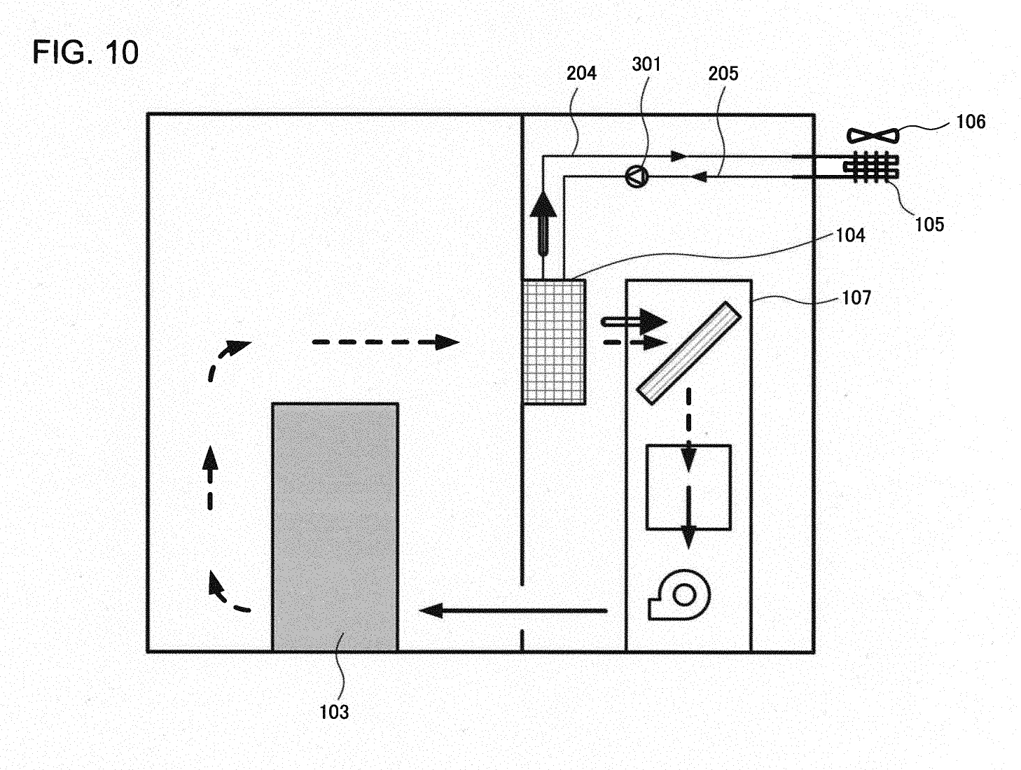

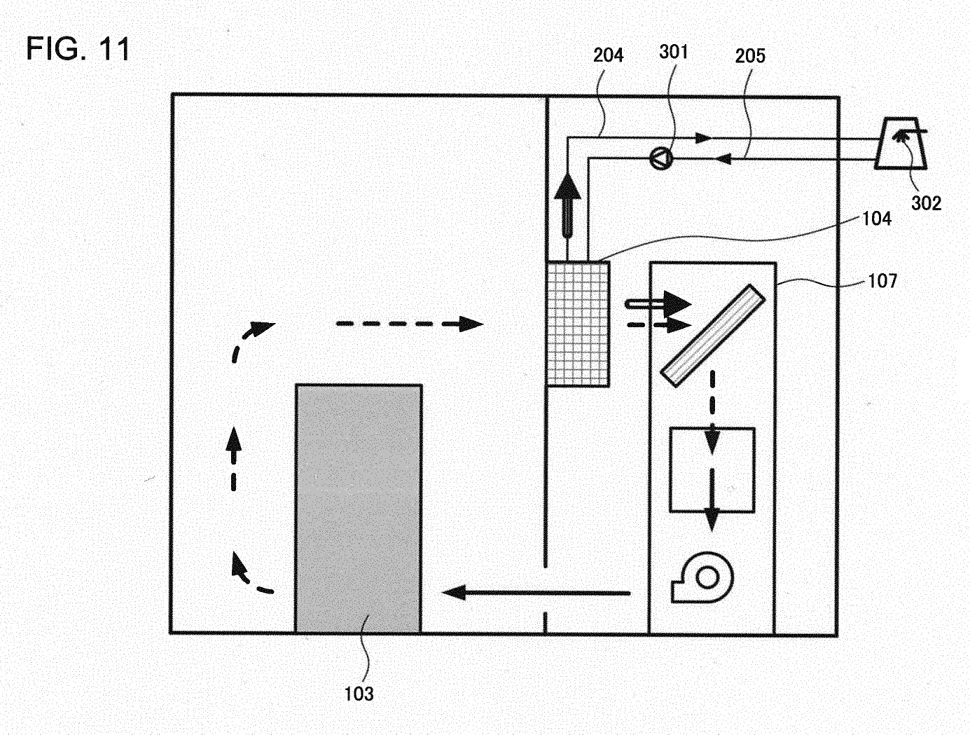

The phase-change cooling apparatus and the phase-change cooling system in each of the above-mentioned example embodiments, as illustrated in FIG. 10, may be configured to include a pump 301 in a flow path of the liquid tube 205 and circulate the refrigerant forcibly. The heat radiator may be constituted by a cooling tower 302 as illustrated in FIG. 11.

Hereinabove, the present invention has been described with above-described example embodiments as exemplary examples. The present invention, however, is not limited to the above-described example embodiments. In other words, various aspects that can be understood by those skilled in the art can be applied to the present invention within the scope of the present invention.

This application is based upon and claims the benefit of priority from Japanese Patent Application No. 2015-074820 filed on Apr. 1, 2015, the disclosure of which is incorporated herein in its entirety by reference.

### REFERENCE SIGNS LIST

10 phase-change cooling apparatus

11, 104 heat receiving section

12, 105 heat radiator

13, 106 fan

14, 204 vapor tube

15, 205 liquid tube

16 controller

21, 107 air conditioner

31 heating section

101 server room

102 machine room

103 server rack

108 heat exchanger

109 refrigerator

110 blower

201 cold air

202 warm air

203 heat

204 vapor tube

301 pump

302 cooling tower

1000 phase-change cooling system

What is claimed is:

1. A phase-change cooling apparatus, comprising:
a heat receiving section configured to vaporize refrigerant liquid stored and produce refrigerant vapor by receiving heat exhausted from a heating section having breathed in cold air;
a heat radiator configured to liquefy the refrigerant vapor and produce refrigerant liquid by radiating heat of the refrigerant vapor to cooling air by a fan;
a vapor tube connecting the heat receiving section to the heat radiator, the refrigerant vapor mainly flowing through the vapor tube;
a liquid tube connecting the heat receiving section to the heat radiator, the refrigerant liquid mainly flowing through the liquid tube; and
a controller configured to control a rotation rate of the fan,
wherein the controller controls the rotation rate of the fan so that a vapor temperature that is a temperature of the refrigerant vapor may approach an intake-air temperature that is a temperature of the cold air.

2. The phase-change cooling apparatus according to claim 1,
wherein the controller controls the rotation rate of the fan so that the vapor temperature may approach the intake-air temperature at a range not in excess of the intake-air temperature.

3. The phase-change cooling apparatus according to claim 1,
wherein the controller compares the vapor temperature with the intake-air temperature, and decreases the rotation rate of the fan if it is determined that the vapor temperature is not larger than the intake-air temperature.

4. The phase-change cooling apparatus according to claim 1,
wherein the controller compares the vapor temperature with the intake-air temperature, and increases the rotation rate of the fan if it is determined that the vapor temperature is larger than the intake-air temperature.

5. The phase-change cooling apparatus according to claim 4,
wherein the controller controls the rotation rate of the fan so that a heat radiator temperature difference may become equal to a threshold temperature difference that is predetermined, where the heat radiator temperature difference is a difference between an inlet temperature that is a temperature of the cooling air flowing into the heat radiator and an outlet temperature that is a temperature of the cooling air flowing away from the heat radiator.

6. The phase-change cooling apparatus according to claim 5,
wherein the threshold temperature difference is the heat radiator temperature difference below which radiation performance of the heat radiator becomes approximately constant.

7. The phase-change cooling apparatus according to claim 1,
wherein the controller
obtains an outside air temperature that is a temperature of outside air flowing into the heat radiator,
controls the rotation rate of the fan in so that an outlet temperature that is a temperature of the cooling air flowing away from the heat radiator may become constant, if the outside air temperature is not larger than a threshold outside air temperature that is predetermined, and
controls the rotation rate of the fan so that a threshold temperature difference may become constant if the outside air temperature is larger than a threshold outside air temperature that is predetermined, where the threshold temperature difference is a heat radiator temperature difference below which radiation performance of the heat radiator becomes approximately constant, and the heat radiator temperature difference is a difference between an inlet temperature that is a temperature of the cooling air flowing into the heat radiator and the outlet temperature.

8. The phase-change cooling apparatus according to claim 1,
wherein the vapor temperature is one of a value obtained by measuring a surface temperature of the vapor tube and a value obtained by measuring a temperature of exhaust air from the heat radiator.

9. A cooling system employing a phase-change cooling apparatus, comprising:
a phase-change cooling apparatus; and
an air conditioner,
wherein the phase-change cooling apparatus includes
a heat receiving section configured to vaporize refrigerant liquid stored and produce refrigerant vapor by receiving heat exhausted from a heating section having breathed in cold air,
a heat radiator configured to liquefy the refrigerant vapor and produce refrigerant liquid by radiating heat of the refrigerant vapor to cooling air by a fan,
a vapor tube connecting the heat receiving section to the heat radiator, the refrigerant vapor mainly flowing through the vapor tube,
a liquid tube connecting the heat receiving section to the heat radiator, the refrigerant liquid mainly flowing through the liquid tube, and
a controller configured to control a rotation rate of the fan,
wherein the controller controls the rotation rate of the fan so that a vapor temperature that is a temperature of the refrigerant vapor may approach an intake-air temperature that is a temperature of the cold air,
wherein the heat receiving section takes in warm air exhausted from the heating section and cools the warm air, and exhausts an air blast reaching an outlet temperature, and
the air conditioner takes in the air blast, produces the cold air at the intake-air temperature, and sends the cold air to the heating section.

10. A method of controlling a phase-change cooling apparatus, on a phase-change cooling apparatus including
a heat receiving section configured to vaporize refrigerant liquid stored and produce refrigerant vapor by receiving heat exhausted from a heating section having breathed in cold air;
a heat radiator configured to liquefy the refrigerant vapor and produce refrigerant liquid by radiating heat of the refrigerant vapor to cooling air by a fan;
a vapor tube connecting the heat receiving section to the heat radiator, the refrigerant vapor mainly flowing through the vapor tube;
a liquid tube connecting the heat receiving section to the heat radiator, the refrigerant liquid mainly flowing through the liquid tube; and
the method comprising:
controlling a rotation rate of the fan so that a vapor temperature that is a temperature of the refrigerant vapor may approach an intake-air temperature that is a temperature of the cold air.

11. The method of controlling the phase-change cooling apparatus according to claim 10,
wherein the controlling the rotation rate of the fan includes controlling the rotation rate of the fan so that the vapor temperature may approach the intake-air temperature at a range not in excess of the intake-air temperature.

12. The method of controlling the phase-change cooling apparatus according to claim 10,
wherein the controlling the rotation rate of the fan includes comparing the vapor temperature with the intake-air temperature, and decreasing the rotation rate of the fan if it is determined that the vapor temperature is not larger than the intake-air temperature.

13. The method of controlling the phase-change cooling apparatus according to claim 10,
wherein the controlling the rotation rate of the fan includes comparing the vapor temperature with the intake-air temperature, and increasing the rotation rate of the fan if it is determined that the vapor temperature is larger than the intake-air temperature.

14. The method of controlling the phase-change cooling apparatus according to claim 13,
wherein the controlling the rotation rate of the fan includes controlling the rotation rate of the fan so that a heat radiator temperature difference may become equal to a threshold temperature difference that is predetermined, where the heat radiator temperature difference is a difference between an inlet temperature that is a temperature of the cooling air flowing into the heat radiator and an outlet temperature that is a temperature of the cooling air flowing away from the heat radiator.

15. The method of controlling the phase-change cooling apparatus according to claim 14,
wherein the threshold temperature difference is the heat radiator temperature difference below which radiation performance of the heat radiator becomes approximately constant.

16. The method of controlling the phase-change cooling apparatus according to claim 10,
wherein the controlling the rotation rate of the fan includes
obtaining an outside air temperature that is a temperature of outside air flowing into the heat radiator,
controlling the rotation rate of the fan in so that an outlet temperature that is a temperature of the cooling air flowing away from the heat radiator may become constant, if the outside air temperature is not larger than a threshold outside air temperature that is predetermined, and
controlling the rotation rate of the fan so that a threshold temperature difference may become constant if the outside air temperature is larger than a threshold outside air temperature that is predetermined, where the threshold temperature difference is a heat radiator temperature difference below which radiation performance of the heat radiator becomes approximately constant, and the heat radiator temperature difference is a difference between an inlet temperature that is a temperature of the cooling air flowing into the heat radiator and the outlet temperature.

17. The method of controlling the phase-change cooling apparatus according to any one of claims 10,
wherein the vapor temperature is one of a value obtained by measuring a surface temperature of the vapor tube and a value obtained by measuring a temperature of exhaust air from the heat receiving section.

18. The method of controlling the phase-change cooling apparatus according to claim 10,
wherein the phase-change cooling apparatus constitutes a cooling system together with an air conditioner,
the heat receiving section takes in warm air exhausted from the heating section and cools the warm air, and exhausts an air blast reaching an outlet temperature, and
the air conditioner takes in the air blast, produces the cold air at the intake-air temperature, and sends the cold air to the heating section.

19. The phase-change cooling apparatus according to claim 2,
wherein the controller compares the vapor temperature with the intake-air temperature, and decreases the rotation rate of the fan if it is determined that the vapor temperature is not larger than the intake-air temperature.

20. The phase-change cooling apparatus according to claim 2,
wherein the controller compares the vapor temperature with the intake-air temperature, and increases the rotation rate of the fan if it is determined that the vapor temperature is larger than the intake-air temperature.
